(19) United States
(12) Patent Application Publication
(10) Pub. No.: US 2015/0214984 A1
(43) Pub. Date: Jul. 30, 2015

(54) METHOD FOR CORRECTING ERROR OF IMPERFECT ENTANGLED QUBIT IN RECEIVER

(71) Applicant: KOREA UNIVERSITY RESEARCH AND BUSINESS FOUNDATION, Seoul (KR)

(72) Inventors: Byung-Kyu Ahn, Seoul (KR); Jun Heo, Seoul (KR)

(73) Assignee: KOREA UNIVERSITY RESEARCH AND BUSINESS FOUNDATION, Seoul (KR)

(21) Appl. No.: 14/602,815

(22) Filed: Jan. 22, 2015

(30) Foreign Application Priority Data
Jan. 24, 2014 (KR) 10-2014-0008850

(51) Int. Cl. H03M 13/29; G06N 99/00

(52) U.S. Cl. CPC H03M 13/29; G06N 99/002

(57) ABSTRACT

Provided is an EA-CWS quantum error correction code for correcting an error on imperfect entangled qubits, and a method for correcting an error using entangled qubits snared between a sender and a receiver includes, after an encoding process to send the entangled qubits, performing an operation of a Pauli error on different stabilizer generators of an EA-CWS code, converting an error occurring on the sender or the receiver to en error correction code in a correctable error form as a result of the operation, and correcting the error on entangled qubits occurring at the side of the sender or the receiver by generating a word operator of a CWS code using the converted error correction code.

### CROSS-REFERENCE TO RELATED APPLICATIONS

This application claims priority under 35 U.S.C. §119 to Korean Patent Application No. 10-2014-0008850 filed on Jan. 24, 2014 in the Korean Intellectual Property Office, the disclosure of which is incorporated herein by reference in its entirety.

### TECHNICAL FIELD

The present disclosure relates to quantum error correction code technology that corrects an error on entangled qubits, and more particularly, to a method for correcting an error on imperfect entangled qubits occurring at the side of a receiver as well as at the side of a sender when the sender and the receiver share the imperfect entangled qubits.

### BACKGROUND

Quantum information communication technology is a new technology emerging in the late of 20th century, which involves operations of storing, transmitting, and processing information based on the principles of quantum physics, and combines quantum physics and information communication technology. Some mysterious phenomena difficult to understand in the general macro world occur in the ultra-micro world where electrons, atoms, or photons or particles of light can be controlled by nanotechnology one by one. The properties of not only particles but also waves are remarkably exhibited, and this world can be described by only quantum mechanics. There is a growing movement toward applications to communication or information processing using three fundamental properties of quantum mechanics including superposition, entanglement, and measurement, and technology for this is termed quantum information technology.

Particularly, attempts are recently being made on applications using these properties in various fields, for example, quantum cryptography communication, quantum processors, quantum simulation, quantum computers, and the like. Quantum information communication uses qubits instead of bits used in a conventional processor. For example, a classical processor with 10 bits carries out 2¹⁰, i.e., 1024 operations in a sequential order, but a quantum processor with 10 qubits carries out 1024 operations simultaneously. That is, a quantum computer can dramatically increase an operation rate using this feature.

On the other hand, as one axis of quantum information communication, various technologies for correcting an error in transmission and reception have been proposed. Non-Patent Literature 1 discloses that error correction codes promise to solve the problems inherent to quantum mechanics, and develop to quantum error correction codes having similar properties to classical error correction codes, called stabilizer codes. Also, Non-Patent Literature 2 introduced an entanglement quantum error correction code scheme that corrects an error occurring on an arbitrary qubit among qubits shared between a sender and a receiver.

### RELATED LITERATURES

### Non-Patent Literature

(Non-Patent Literature 1) Gottesman, D.: Ph.D. thesis, Caltech., 1997
(Non-Patent Literature 2) Shaw, Bilal., Wilde, Mark M., Oreshkov, Ognyan., Kremsky, Isaac., Lidar, Daniel A.: Encoding one logical qubit into six physical qubits., Phys. Rev. A. 78, 012337, 2008

### SUMMARY

The present disclosure is directed to overcoming the limitation of classical entanglement-assisted quantum error correction codes that fail to correctly deal with an error occurring in an actual situation not only on the sender side but also on the receiver-side entangled qubits although an assumption is that an error does not occur on the receiver-side entangled qubits, and is further directed to solving the problem with error correction capability reduction in the application of the classical error correction codes.

In one aspect, there is provided is a method for correcting an error using entangled qubits (ebits) shared between a sender and a receiver, including: the sender correcting an error occurring on a channel using an entanglement-assisted codeword stabilized quantum (EA-CWS) code; and the receiver correcting an error occurring on received entangled qubits (ebits) using a stabilizer code, wherein two error correction codes of the EA-CWS code and the stabilizer code are combined to generate a combination code.

In the error correction method according to an exemplary embodiment, the receiver may correct not only an error occurring on a sending channel but also an error occurring on the receiver after passing over the sending channel, through the stabilizer code included in the combination code.

In another aspect, there is provided a method for correcting an error using entangled qubits shared between a sender and a receiver, including: after an encoding process to send the entangled qubits, performing an operation of a Pauli error on different stabilizer generators of an EA-CWS code; converting an error occurring on the sender or the receiver to an error correction code in a correctable error form as a result of the operation; and correcting the error on entangled qubits occurring at the side of the sender or the receiver by generating a word operator of a CWS code using the converted error correction code.

In the error correction method according to another exemplary embodiment, the different stabilizer generators may include X operators on one qubit at different positions, the X operator describing an error, and through the operation of the Pauli error, a single error occurring on the sender may be generated as an effective error consisting only of a Z operator and an I operator, and the effective error may be converted to a correctable binary error.

In the error correction method according to another exemplary embodiment, an error occurring on the sender and an error occurring on the receiver may form an equivalent conversion relationship, and the sender may correct an error on the receiver side using multi-error correction.

Further, there is provided a computer-readable recording medium having stored therein a program for causing a computer to execute the method for correcting an error using entangled qubits shared between a sender and a receiver.

According to the exemplary embodiments of the present disclosure, an error occurring on both sides of the sender and the receiver may be corrected by employing one error correction code using two error correction codes, EA-CWS and stabilizer codes or a unique trait of EA-CWS, and thus, even if an error occurs on the receiver-side entangled qubits, the error may be corrected, thereby improving the performance of quantum error correction codes.

### BRIEF DESCRIPTION OF THE DRAWINGS

FIG. 1 is a diagram illustrating an error correction code model for correcting an error using two quantum error correction codes according to an exemplary embodiment of the present disclosure.

FIG. 2 is a flowchart illustrating a method for correcting an error on entangled qubits (ebits) shared between a sender and a receiver using two quantum error correction codes according to an exemplary embodiment of the present disclosure.

FIG. 3 is a diagram illustrating a comparison of word stabilizers before and after encoding in the error correction method of FIG. 2 according to an exemplary embodiment of the present disclosure.

FIG. 4 is a flowchart illustrating a method for correcting an error on entangled qubits shared between a sender and a receiver using one quantum error correction code according to another exemplary embodiment of the present disclosure.

FIG. 5 illustrates a type and a number of errors correctable by the error correction method of FIG. 4 according to another exemplary embodiment of the present disclosure.

FIG. 6 is a diagram illustrating a table of EA-CWS codes with imperfect entangled qubits eligible for the error correction method of FIG. 4 according to another exemplary embodiment of the present disclosure.

### DETAILED DESCRIPTION OF MAIN ELEMENTS

| | |
|---|---|
| 10: sender | 20: receiver |

### DETAILED DESCRIPTION OF EMBODIMENTS

Prior to the description of the exemplary embodiments of the present disclosure, a brief introduction to entanglement-assisted quantum error correction technology and a review on problems of entanglement-assisted CWS (EA-CWS) using the same is followed by an introduction to technical means employed in the exemplary embodiments of the present disclosure.

A codeword stabilized (CWS) quantum code is defined as a unifying quantum error correction code capable of constructing additive and non-additive codes from a ring graph and a classical binary code. However, the CWS code constructed using the classical binary code based on the ring graph still has a limitation of failure to find a code with a minimum distance greater than 4.

The entanglement-assisted quantum error correction code may have some advantages by sharing entangled qubits between a receiver and a sender. Particularly, if one of the special properties of quantum information, entangled qubits (ebits), is utilized, a capacity increase effect may arise from much of a quantum information system, and using this property of entangled qubits, a minimum distance may be expanded.

When this property is applied to classical CWS, a minimum distance may be expanded greater than or equal to 4. The entanglement-assisted CWS (EA-CWS) code is a quantum error correction code of expanded concept beyond the limitation. In the EA-CWS code, both a sender and a receiver use maximally entangled qubits. Using this, the CWS code may generate non-additive codes with a minimum distance greater than 4, and besides, may overcome the dual-containing constraint problem through the use of entangled qubits.

Meanwhile, existing entanglement-assisted quantum error correction codes assume that an error does not occur on the receiver-side entangled qubits. However, in an actual situation, an error may occur on the receiver-side entangled qubit as well as on the sender side. Unfortunately, because the existing quantum error correction codes using entanglement assume that an error does not occur because the receiver-side entangled qubits do not pass over a transmit channel, when the classical error correction codes are applied, error correction capability reduces. Thus, in this case, there is a need for a design scheme which may improve the performance of quantum error correction codes by applying entangled qubits to the CWS code.

By the above reason, the exemplary embodiments of the present disclosure described below aim to propose a code design scheme for classical EA-CWS quantum error correction codes in the form of correcting not only an a sender-side error but also a receiver-side error. Particularly, the exemplary embodiments of the present disclosure present a design scheme of a quantum error correction code that may be applicable even when sharing imperfect entangled qubits, dissimilar to the classical EA-CWS codes sharing perfect entangled qubits.

As previously noted, the quantum error correction codes using entanglement generally assume that an error does not occur because most of receiver-side entangled qubits do not pass over a transmit channel. However, in an actual situation, an error inevitably occurs on a transmit channel and even receiver-side entangled qubits, which causes a reduction in error correction capability of the existing quantum error correction codes. Accordingly, the exemplary embodiments of the present disclosure require an error correction code that may correct an error occurring on the sender side as well as an error occurring on the receiver-side entangled qubits and an error occurring on both sides of the sender and the receiver at the same time.

The exemplary embodiments of the present disclosure are based on a CWS code and an entanglement-assisted quantum error correction code (EA-QECC) among the classical quantum error correction codes. Further, an EA-CWS code may be generated by combining the two codes. The EA-CWS code has many benefits from the use of entangled qubits. Particularly, the EA-CWS code may be used for the purpose of improving the code performance or alleviating a constraint. The entanglement-assisted quantum error correction (EA-QEC) code presents a method which may overcome a dual-containing constraint as an obstacle to design of the quantum error correction code from the classical error correction codes using entangled qubits shared between a sender and a receiver. Also, by the use of the entangled qubits, a minimum distance or a code rate may increase.

The EA-CWS code is a quantum error correction code that, using this advantage, assumes an error does not occur on the receiver-side entangled qubits and applies entangled qubits to a classical CWS code, to improve the code performance. A basic notation uses [[n,K,d;c]], representing a quantum code to encode with a K-dimensional code space and a minimum distance d (d is a positive integer) using n (n is a positive integer) physical qubits and c (c is a positive integer) entangled qubits. Using this, the CWS code may systematically construct non-additive codes with a minimum distance greater than 4.

However, in an actual situation, an error inevitably occurs on not only a sending channel but also receiver-side entangled qubits, resulting in a reduction in error correction capability of error correction codes. Accordingly, the exemplary embodiments of the present disclosure designed a scheme which uses an error correction code to correct an error occurring at both sides of a sender and a receiver. Two methods for designing a quantum error correction code with a minimum distance of d using c entangled qubits shared between a sender and a receiver by employing a CWS scheme are described below.

Hereinafter, the exemplary embodiments of the present disclosure are described in detail with reference to the drawings. However, a detailed description of known functions or constructions that may obscure the essence of the present disclosure in the following description and the accompanying drawings is omitted herein.

### First Embodiment

A first scheme is a scheme designed, in consideration of a situation in which an error occurs on receiver-side entangled qubits, to impede the resulting error correction capability reduction. To this end, two error correction codes are used; at the sender side, a [[n,k,d_{A};c]] EA-CWS code is used, and at the receiver side, a [[m,c,d_{B}]] stabilizer code is used. Also, parameters used in the stabilizer code represent encoding with c (c is a positive integer)-dimensional code space and a minimum distance d_{B} (d_{B} is a positive integer) using m (m is a positive integer) physical qubits, and here, c equals a number of entangled qubits. That is, the first scheme uses a combination of the EA-CWS code and the stabilizer code, namely, a combination code.

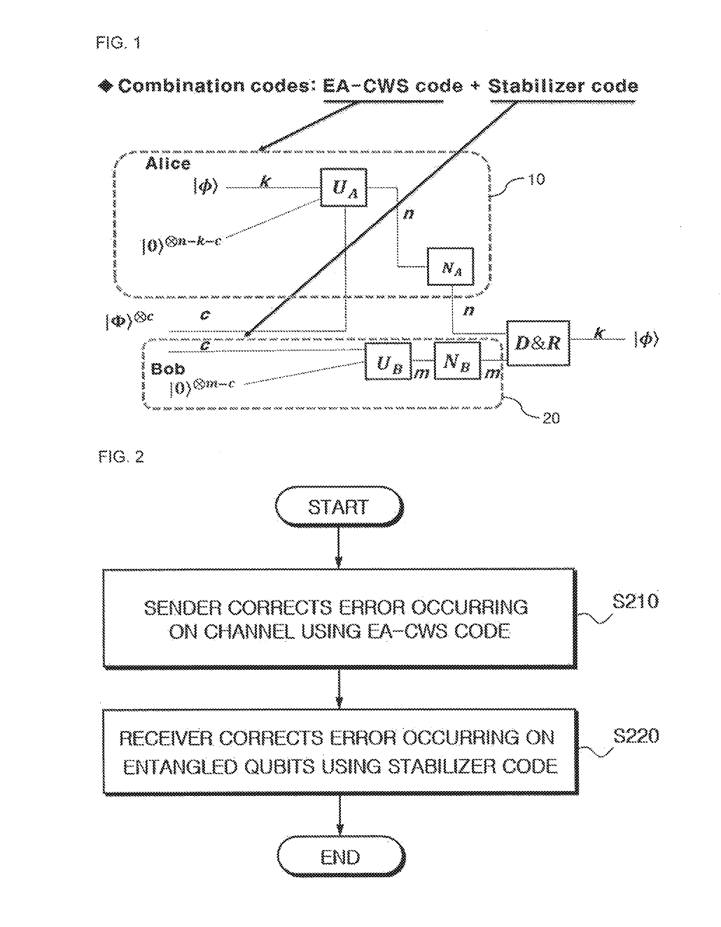

FIG. 1 is a diagram illustrating an error correction code model for correcting an error using two quantum error correction codes according to an exemplary embodiment of the present disclosure.

Referring to FIG. 1, the code construction is presented, taking into account a situation in which an error occurs on entangled qubits at the side of a receiver 20, to impede the resulting error correction capability reduction.

To this end, the combination code, or a combination of the classical EA-CWS code and the stabilizer code added to the side of the receiver 20 are used. Going into details about the basic construction of the code, as presented in FIG. 1, at the side of a sender 10, the EA-CWS code is used to correct an error occurring on a channel, and at the side of the receiver 20, the stabilizer code is used to correct an error occurring on entangled qubits.

The stabilizer code is a very important code in the quantum error correction code. The stabilizer code has very similar properties to a linear error correction code among classical error correction codes. Before describing the stabilizer code, let us briefly describe the classical linear block code, and in the classical linear block code, each codeword is constructed by a linear combination of a generator matrix and a row vector, and the overall codeword may be regarded as a space which spans the generator matrix. Decoding of the linear block codes involves detecting whether an error is present or absent using a parity check matrix and recovering a codeword using an error syndrome.

The stabilizer code is an error correction code that recovers an error using a stabilizer group forming an abelian group among subsets of a Pauli group. A stabilizer codeword corresponds to a space stabilized by the stabilizer group, and has a characteristic that the codeword space does not change even if an operation is performed with any operator belonging in the stabilizer group. To express the stabilizer group including numerous operators in a simpler manner, a stabilizer generator may be contemplated. The stabilizer generator is a base element of the stabilizer group, and the stabilizer group may be generated through a linear combination of stabilizer generators. Thus, the codeword stabilized by the stabilizer group is said to be the same as the codeword stabilized by the stabilizer generator.

A decoding algorithm of the stabilizer code is based on syndrome like the classical linear block code. In the stabilizer code, an error syndrome is determined based on whether a commutative requirement between a stabilizer generator and a channel error is satisfied or not. Generally, for all operators belonging in the Pauli group, there are two relationships; the commutative requirement between each operator is satisfied, and the commutative requirement between each operator is not satisfied.

Both an error occurring on a channel and a stabilizer generator are elements of a Pauli group, and when a commutative requirement between the channel error E and the stabilizer generator S_{c} is satisfied, [S_{c},E]=0 is represented, and otherwise, [S_{c},E]=1 is represented. The error syndrome is defined as a vector of a size equal to a number of stabilizer generators. Each element of the error syndrome has a value of ‘0’ or ‘1’, and each value represents whether the commutative requirement between the stabilizer generator and the channel error corresponding to the syndrome elements is satisfied or not. This is the same result as, in the classical error correction code, a received code having ‘0’ when a parity check equation is satisfied and the received code having ‘1’ when the parity check equation is not satisfied due to an error, and in the stabilizer code, the stabilizer generator serves as a parity check equation of the classical error correction code.

As a typical class of the stabilizer code, CSS codes are known. A dual-code requirement of the CSS code is equivalent to a condition for satisfying the commutative requirement between each stabilizer generator in the stabilizer code. The dual-code requirement of the linear block code with the parity check equation corresponding to the stabilizer generator should be satisfied.

Currently, the stabilizer code is mostly formulated using a dual code of the classical linear block code. However, due to the dual code requirement to be satisfied, the classical linear block code has a limitation on applications of high performance codes (which may be low-density parity-check (LDPC) codes, for example). To solve this problem, an entanglement-assisted quantum error correction code scheme using entangled states is being researched in recent years. When the entangled states are used, even if the dual code requirement is not satisfied, the classical linear block code scheme may be applied to the stabilizer code, and accordingly, a variety of classical error correction code schemes with high performance may be applied to a quantum error correction code scheme.

A common property of the quantum error correction code, typically, the CSS code and the stabilizer code, being researched is that a classical error correction code scheme may be easily applied to a quantum error correction code in spite of a great difference between a quantum information system and a classical information system in constructing the quantum error correction code. Along with this, recently, studies are being made on a method that constructs a quantum error correction code using a classical code based a quantum entanglement phenomenon even though the dual code requirement of the classical linear block code is absent, and such studies are making enough progress to make it theoretically possible to apply most of classical error correction code schemes to a quantum error correction code scheme.

FIG. 2 is a flowchart illustrating a method for correcting an error on entangled qubits (ebits) shared between a sender and a receiver using two quantum error correction codes according to an exemplary embodiment of the present disclosure, including the following steps.

In S210, the sender corrects an error occurring on a channel, using an EA-CWS (entanglement-assisted codeword stabilized quantum) code. In S220, the receiver corrects an error occurring on received entangled qubits (ebits) using a stabilizer code. Here, two error correction codes, i.e., the EA-CWS code and the stabilizer code, are combined to generate a combination code. Particularly, the receiver may correct not only an error occurring on a sending channel but also an error occurring at the receiver after passing over the sending channel, through the stabilizer code included in the combination code.

The classical quantum error correction code with perfect entangled qubits assumes only a channel error occurs while sending and receiving and corrects only such a channel error using the EA-CWS code, whereas the quantum error correction code with imperfect entangled qubits follows the same process of correcting a channel error using the EA-CWS code, but needs additional consideration of a storage error occurring on entangled qubits at the side of the receiving end Bob.

When the storage error occurs on the entangled qubits at the side of the receiving end, the quantum error correction code using entanglement, namely, the EA-CWS code, uses the stabilizer code to correct the error. Based on a range of the error occurring at the receiver end Bob, a parameter value of [[m,c,d_{B}]] to be applied changes, and here, an available parameter value of the stabilizer code may use values in Markus's table of code parameters (M. Grassl, “Bounds on the minimum distance of linear codes and quantum codes,”) as shown in the following Table 1.

TABLE 1

| | k | | | | | | | | | | | | | | | | | | | | | | | |
|---|---|---|---|---|---|---|---|---|---|---|---|---|---|---|---|---|---|---|---|---|---|---|---|---|
| n | 0 | 1 | 2 | 3 | 4 | 5 | 6 | 7 | 8 | 9 | 10 | 11 | 12 | 13 | 14 | 15 | 16 | 17 | 18 | 19 | 20 | 21 | 22 | 23 24 25 26 27 28 29 30 |
| 1 | 1 | 1 | | | | | | | | | | | | | | | | | | | | | | |
| 2 | 2 | 1 | 1 | | | | | | | | | | | | | | | | | | | | | |
| 3 | 2 | 1 | 1 | 1 | | | | | | | | | | | | | | | | | | | | |
| 4 | 2 | 2 | 2 | 1 | 1 | | | | | | | | | | | | | | | | | | | |
| 5 | 3 | 3 | 2 | 1 | 1 | 1 | | | | | | | | | | | | | | | | | | |
| 6 | 4 | 3 | 2 | 2 | 2 | 1 | 1 | | | | | | | | | | | | | | | | | |
| 7 | 3 | 3 | 2 | 2 | 2 | 1 | 1 | 1 | | | | | | | | | | | | | | | | |
| 8 | 4 | 3 | 3 | 3 | 2 | 2 | 2 | 1 | 1 | | | | | | | | | | | | | | | |
| 9 | 4 | 3 | 3 | 3 | 2 | 2 | 2 | 1 | 1 | 1 | | | | | | | | | | | | | | |
| 10 | 4 | 4 | 4 | 3 | 3 | 2 | 2 | 2 | 2 | 1 | 1 | | | | | | | | | | | | | |
| 11 | 5 | 5 | 4 | 3 | 3 | 3 | 2 | 2 | 2 | 1 | 1 | 1 | | | | | | | | | | | | |
| 12 | 6 | 5 | 4 | 4 | 4 | 3 | 3 | 2 | 2 | 2 | 2 | 1 | 1 | | | | | | | | | | | |
| 13 | 5 | 5 | 4 | 4 | 4 | 3 | 3 | 3 | 2 | 2 | 2 | 1 | 1 | 1 | | | | | | | | | | |
| 14 | 6 | 5 | 5 | 4-5 | 4 | 4 | 4 | 3 | 3 | 2 | 2 | 2 | 2 | 1 | 1 | | | | | | | | | |
| 15 | 6 | 5 | 5 | 5 | 4 | 4 | 4 | 3 | 3 | 3 | 2 | 2 | 2 | 1 | 1 | 1 | | | | | | | | |
| 16 | 6 | 6 | 6 | 5 | 5 | 4-5 | 4 | 4 | 3 | 3 | 3 | 2 | 2 | 2 | 2 | 1 | 1 | | | | | | | |
| 17 | 7 | 7 | 6 | 5-6 | 5 | 4-5 | 4-5 | 4 | 4 | 4 | 3 | 3 | 2 | 2 | 2 | 1 | 1 | 1 | | | | | | |
| 18 | 8 | 7 | 6 | 5-6 | 5-6 | 5 | 5 | 4 | 4 | 4 | 3 | 3 | 2 | 2 | 2 | 2 | 2 | 1 | 1 | | | | | |
| 19 | 7 | 7 | 6 | 5-6 | 5-6 | 5-6 | 5 | 4-5 | 4 | 4 | 3-4 | 3 | 3 | 2 | 2 | 2 | 2 | 1 | 1 | 1 | | | | |
| 20 | 8 | 7 | 6-7 | 6-7 | 6 | 5-6 | 5-6 | 4-5 | 4-5 | 4 | 4 | 3-4 | 3 | 3 | 2 | 2 | 2 | 2 | 2 | 1 | 1 | | | |
| 21 | 8 | 7 | 6-7 | 6-7 | 6-7 | 6 | 5-6 | 5-6 | 4-5 | 4-5 | 4 | 4 | 3-4 | 3 | 3 | 3 | 2 | 2 | 2 | 1 | 1 | 1 | | |
| 22 | 8 | 7-8 | 6-8 | 6-7 | 6-7 | 6-7 | 5-6 | 5-6 | 5-6 | 4-5 | 4-5 | 4 | 4 | 3-4 | 3 | 3 | 2 | 2 | 2 | 2 | 2 | 1 | 1 | |

According to the code notation previously defined, a vertical axis represents a value of m (denoted as n in Table 1), and a horizontal axis represents a value of c (denoted as k in Table 1). Also, numbers in the middle represent a value of a minimum distance d based on the values of m and c. The table values correspond to optimized values of stabilizer codes found so far and arranged in the form of a table, and most of stabilizer essays are based on these code values.

In the code according to the exemplary embodiment presented by the present disclosure, when two errors occur at the side of the receiving end, a stabilizer code with a minimum distance d greater than or equal to 5 is needed to correct the errors, and thus, a smallest m 11 of qubits is selected from available qubits of d=5 in Table 1. Also, in Table 1, 0 and 1 are found as the value of c used herein, and the errors are corrected using the same value of c as a [[n,k,d_{A};c]] EA-CWS code used to correct a channel error.

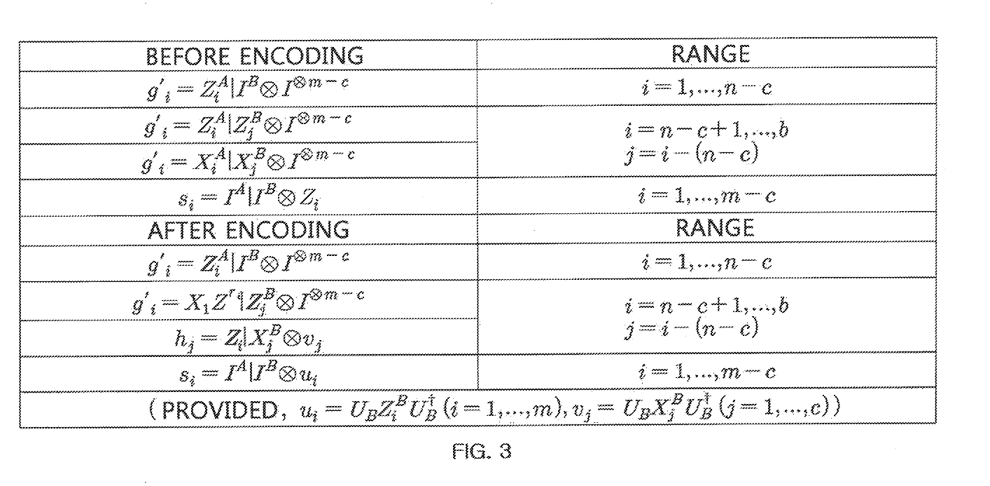

FIG. 3 is a diagram illustrating a comparison of word stabilizers before and after encoding in the error correction method of FIG. 2 according to an exemplary embodiment of the present disclosure.

For example, when a combination code of a ((7,4,5;4)) code and a [[11,4,3]] stabilizer code is used, two errors occurring on a channel may be corrected like the classical CWS quantum error correction code, and one error occurring at the receiver side may be corrected as well. In comparison to a [[n+m,k,d]]=[[18,2,6]] standard stabilizer code which is an equivalent error correction code, correction capability of errors actually occurring on a channel is equally two, but for physical qubits to be transmitted via a channel to transmit the same information, the EA-CWS code transmits seven qubits and thus is found to have higher channel efficiency than the stabilizer code that needs to transmit eighteen physical qubits. Through this, not only a sender-side error but also a receiver-side error may be corrected, and a code with improved error correction capability over the classical quantum error correction code may be formulated.

### Second Embodiment

A second scheme corrects both a sender-side error and a receiver-side error using one error correction code. To this end, a unique trait of EA-CWS is used, and the unique trait is that after an encoding process, different stabilizer generators have each an X operator on one qubit at different positions.

Using this trait, this scheme may convert a single error occurring at the side of the sender (hereinafter referred to as Alice), similar to the classical EA-CWS code, to an effective error consisting only of Z and I operators through an operation of a stabilizer and a Pauli error, and may convert an error occurring at the side of the receiver (hereinafter referred to as Bob) to an effective error as well. Here, the Z operator corresponds to an operator representing a phase flip, and the I operator corresponds to an identity operator. A quantum error corresponds to an error consisting largely of X, Y, Z, and a combination thereof, and is specified as shown in the following Equation 1.

[Equation 1]

Quantum Errors
iε{0,1} and ī=i⊕1
Bit flip ‘X’: |i [symbol] →|ī [symbol]
Phase flip ‘Z’: |i [symbol] →(−1)ⁱ|i [symbol]
Bit-phase flip ‘Y’: |i [symbol] →(−1)^{ī}j|ī [symbol] =jZX|i [symbol]
In general, E=e₁I+e₂X+e₃Y+e₄Z,
   where I: identity operator
      eₖ: complex number

The channel error converted to ‘Z’ and ‘I’ may be instead thought as a binary error respectively corresponding to ‘0’ and ‘1’, and the error may be corrected using the classical error correction code that corrects a binary error induced by a word stabilizer. For more details, a reference may be made to the following paper: A. Cross, G. Smith, J. A. Smolin, and B. Zeng, “Codeword Stabilized Quantum codes” IEEE T. Inform. Theory 55, 433, 2009, reporting that in CWS codes, particularly, CWS codes in standard form, a single Pauli error Z, X, Y=XZ acting on a codeword may be replaced by an error consisting only of Z by a stabilizer generator.

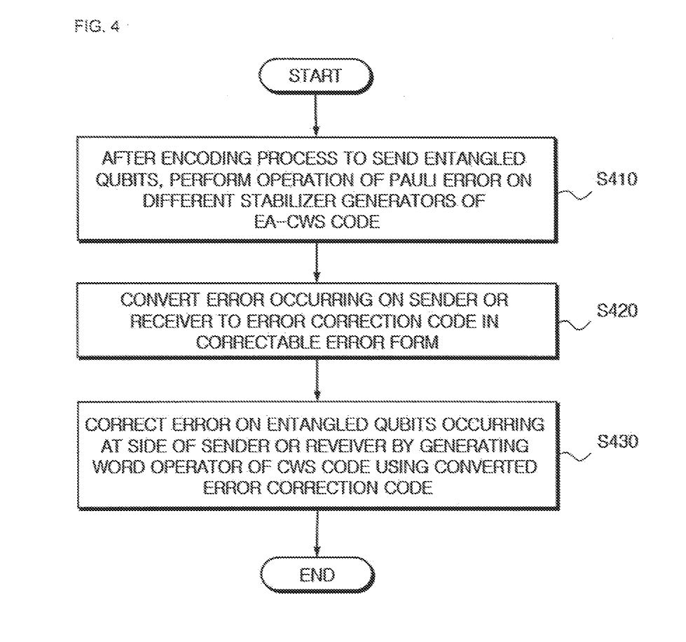

FIG. 4 is a flowchart illustrating a method for correcting an error on entangled qubits shared between a sender and a receiver using one quantum error correction code according to another exemplary embodiment of the present disclosure, including the following steps.

In S410, an error correcting apparatus performs an operation of a Pauli error on different stabilizer generators of an EA-CWS code, after an encoding process to transmit entangled qubits.

In S420, the error correcting apparatus converts an error occurring at the side of the sender or the receiver to an error correction code in correctable error form, as a result of the operation of S410.

In S430, the error correcting apparatus corrects the error on entangled qubits occurring at the side of the sender or the receiver by generating a word operator of a CWS code using the error correction code converted through S420.

Here, the different stabilizer generators include an X operator that describes an error on one qubit at different positions, and thus, a single error occurring at the side of the sender is converted to an effective error consisting only of a Z operator and an I operator through the Pauli error operation, and the effective error is converted to a correctable binary error.

Dissimilar to the first scheme, the second scheme corrects both a sender-side error and a receiver-side error using one error correction code. To this end, the second scheme uses a unique trait of EA-CWS that after encoding, each of different stabilizer generators has an X operator on one qubit at different positions as shown in the following Equation 2.

$$\{ \begin{matrix}{X}_{1} {Z}_{2} I … {IZ}_{n} \vert {I}^{⊗ c} \\ {Z}_{1} {X}_{2} {Z}_{3} I … I \vert {I}^{⊗ c} \\ {IZ}_{2} {X}_{3} {Z}_{4} I … I \vert {I}^{⊗ c} \\ … \\ I … {IZ}_{n - c - 1} {X}_{n - c} {Z}_{n - c + 1} I … I \vert I \\ … \\ I … {IZ}_{n - 2} II \vert I … {IX}_{c - 2} II \\ I … {IIZ}_{n - 1} I \vert I … {IIX}_{c - 1} I \\ I … {IIIIIZ}_{n} \vert I … {IIIX}_{c}\end{matrix} \qquad [ Equation 2 ]$$

In Equation 2, it can be seen that each stabilizer generator includes an X operator describing an error, and one X operator is included at each of different positions.

Using this feature, the second scheme may convert a single error occurring at the side of the sender Alice, similar to the classical EA-CWS code, to an effective error consisting only of Z and I operators through an operation of a stabilizer and a Pauli error, and may convert an error occurring at the side of the receiver Bob to an effective error as well.

Thus, the channel error converted to ‘Z’ and ‘I’ may be instead thought as a binary error respectively corresponding to ‘0’ and ‘1’, and a word operator of a CWS code may be constructed using the classical error correction code that corrects a binary error induced by a word stabilizer.

Here, what is important is that an equivalent conversion relationship is built between a sender-side error and a receiver-side error. Using the built equivalent relationship, multi-error correction capability is additionally provided to the sender side dissimilar to the classical EA-CWS code. Also, it can be seen that with the use of the equivalent conversion relationship of the errors occurring at the both sides of the sender and the receiver, capability of correcting a receiver-side error through the multi-error correction at the sender side is obtained.

Thus, according to another exemplary embodiment of the present disclosure described in the foregoing, the sender may correct the receiver-side error because the sender-side error and the receiver-side error form an equivalent conversion relationship.

Also, in the second scheme, the word operator is an operator which is performed at both sides of the sender and the receiver in the same manner as the classical EA-CWS code. On an initially assumption, an encoding operation is to be performed at the sender, and thus, there is a need for an operation of erasing a receiver operator present in the word operator by applying a word stabilizer to the word operator. The word operator actually consists only of a ‘Z’ operator, which allows the operation of the word operator to be independently performed only at the sender by applying a word stabilizer operator with a ‘Z’ operator at the receiver to a word operator with a ‘Z’ operator equally at the receiver.

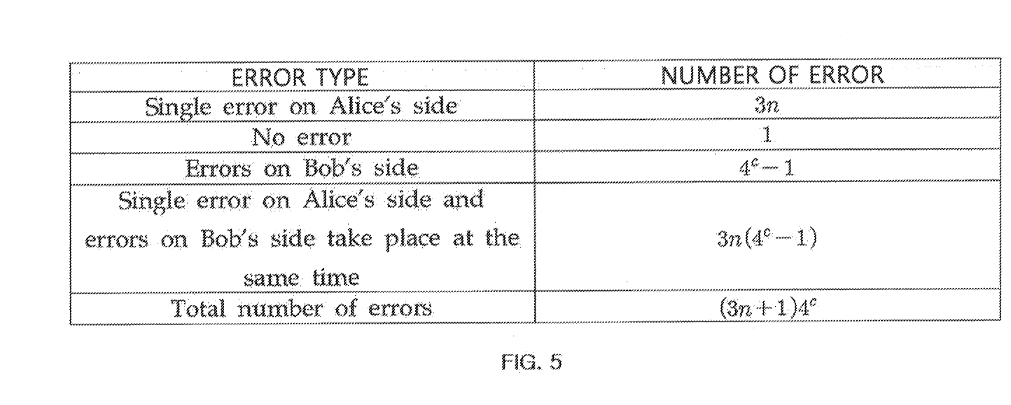

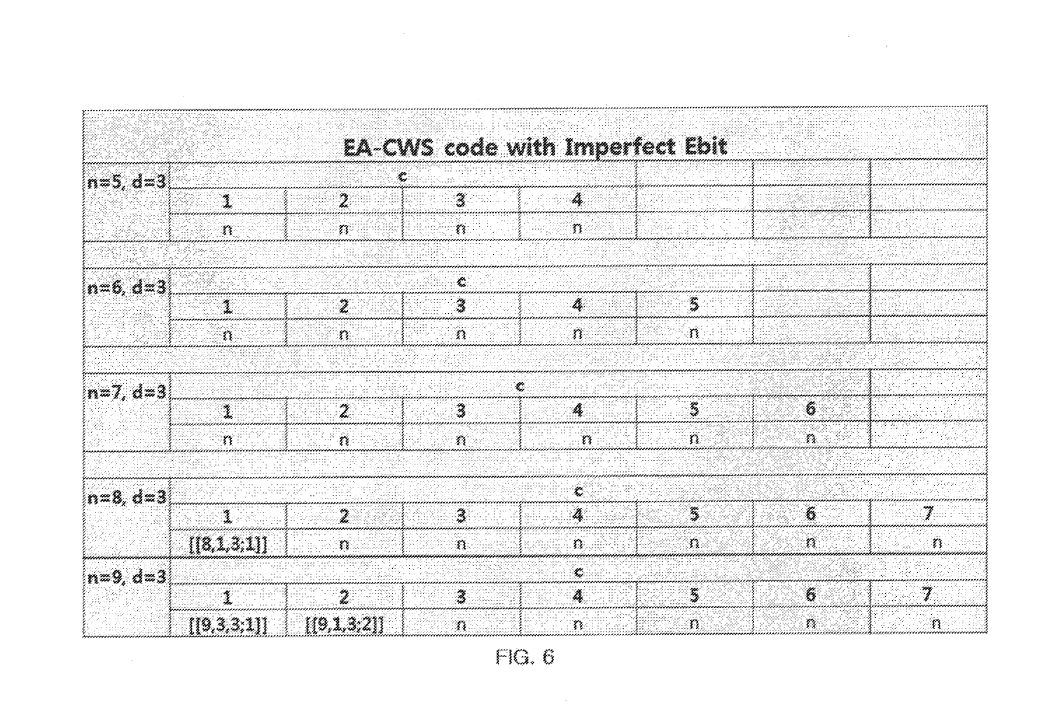

Now take a look at a type of error correctable through this process, it can be seen that a result of FIG. 5 is produced.

FIG. 5 illustrates a type and a number of errors correctable by the error correction method of FIG. 4 according to another exemplary embodiment of the present disclosure. As appears out of the result of the table of FIG. 5, when a minimum distance is equal to 3, a classical ((n,K,d;c)) EA-CWS code corrects 3n single errors only at the side of Alice, while the second scheme using the EA-CWS code with imperfect entangled qubit corrects (3n+1)4^{c} errors with superiority over the classical code because all errors occurring at both sides of the sender and the receiver are taken into account.

Also, as an example of actual code design using a design scheme of the EA-CWS code with imperfect entangled qubits, EA-CWS codes of FIG. 6 are given, with a minimum distance equal to 3.

FIG. 6 is a diagram illustrating a table of EA-CWS codes with imperfect entangled qubits eligible for the error correction method of FIG. 4 according to another exemplary embodiment of the present disclosure, showing EA-CWS codes based on n, d, and c.

The exemplary embodiment of the present disclosure described herein propose a method of designing an EA-CWS code with imperfect entangled qubits in more generic and various actual situations than the classical EA-CWS code.

The classical code improves the performance of quantum error correction codes by applying entanglement qubits to a codeword quantum error correction code scheme (codeword stabilized (CWS) quantum codes), but this is effective only under the assumption that an error does not occur because the receiver-side entangled qubits do not pass over a sending channel. However, because an error may occur on the receiver-side entangled qubits in an actual situation, through development of a quantum error correction code applicable to such a case, an error occurring at both sides of the sender and the receiver may be corrected.

The exemplary embodiments of the present disclosure may be embodied as a computer-readable code in a computer-readable recording medium. The computer-readable recording medium includes any type of recording device storing data readable by a computer system.

Examples of the computer-readable recording medium include those that are implemented in the form of ROM, RAM, CD-ROM, magnetic tapes, floppy discs, optical data recording devices, and the like. Also, the computer-readable recording medium may be distributed over network-coupled computer systems so that the computer-readable code is stored and executed in a distributed fashion. Also, functional programs, codes, and code segments for implementing the present disclosure may be easily inferred by programmers in the technical field to which the present disclosure belongs.

Hereinabove, the present disclosure has been described in connection with various exemplary embodiments. It should be noted modifications may be made to the present disclosure by person having ordinary skill in the technical field to which the present disclosure belongs without departing from the fundamental principles of the present disclosure. Therefore, the disclosed embodiments should be considered in illustrative aspects rather than limiting aspects. It should be understood that the scope of the present disclosure falls within the appended claims, not in the detailed description, and all changes within the equivalent range are included in the present disclosure.

What is claimed is:

1. A method for correcting an error using entangled qubits (ebits) shared between a sender and a receiver, comprising:
the sender correcting an error occurring on a channel using an entanglement-assisted codeword stabilized quantum (EA-CWS) code; and
the receiver correcting an error occurring on received entangled qubits (ebits) using a stabilizer code,
wherein two error correction codes of the EA-CWS code and the stabilizer code are combined to generate a combination code.

2. The method according to claim 1, wherein the receiver corrects not only an error occurring on a sending channel but also an error occurring on the receiver after passing over the sending channel, through the stabilizer code included in the combination code.

3. A method for correcting an error using entangled qubits shared between a sender and a receiver, comprising:
performing an operation of a Pauli error on different stabilizer generators of an EA-CWS code, after an encoding process to send the entangled qubits;
converting an error occurring on the sender or the receiver to an error correction code in a correctable error form as a result of the operation; and
correcting the error on entangled qubits occurring at the side of the sender or the receiver by generating a word operator of a CWS code using the converted error correction code.

4. The method according to claim 3, wherein the different stabilizer generators include X operators on one qubit at different positions, the X operator describing an error, and through the operation of the Pauli error, a single error occurring on the sender is generated as an effective error consisting only of a Z operator and an I operator, and the effective error is converted to a correctable binary error.

5. The method according to claim 3, wherein an error occurring on the sender and an error occurring on the receiver form an equivalent conversion relationship, and the sender corrects an error on the receiver side using multi-error correction.
